(19) United States
(12) Patent Application Publication
(10) Pub. No.: US 2025/0167104 A1
(43) Pub. Date: May 22, 2025

(54) SEMICONDUCTOR PACKAGE

(71) Applicant: Taiwan Semiconductor Manufacturing Company, Ltd., Hsinchu (TW)

(72) Inventors: Chien-Hao HSU, Zhubei City (TW); Wei-Hsiang TU, Hsinchu city (TW); Kuo-Chin CHANG, Chiayi City (TW); Kathy Wei YAN, Hsinchu (TW); Shin-Puu JENG, Hsinchu (TW)

(73) Assignee: Taiwan Semiconductor Manufacturing Company, Ltd., Hsinchu (TW)

(21) Appl. No.: 18/517,892

(22) Filed: Nov. 22, 2023

(51) Int. Cl. H01L 23/522; H01L 23/00; H01L 23/528

(52) U.S. Cl. CPC H01L 23/5226; H01L 23/5283; H01L 24/05; H01L 24/13; H01L 24/16; H01L 24/73; H01L 24/32; H01L 2224/02331; H01L 2224/02373; H01L 2224/05582; H01L 2224/0569; H01L 2224/13018; H01L 2224/16145; H01L 2224/16225; H01L 2224/32145; H01L 2224/32225; H01L 2224/73204; H01L 2924/182

(57) ABSTRACT

A semiconductor package is provided. The semiconductor package includes a semiconductor substrate, a lower interconnect structure, an upper interconnect structure, a conductive pad, and a pillar bump. The lower interconnect structure is formed over the semiconductor substrate. The lower interconnect structure includes a plurality of lower dielectric layers. The lower interconnect structure also includes a plurality of lower metal lines and a plurality of lower metal vias formed in the lower dielectric layers. The upper interconnect structure is formed over the lower interconnect structure. The conductive pad is formed over the upper interconnect structure. The pillar bump structure is in direct contact with the conductive pad. The pillar bump structure includes at least two protrusions protruding toward the conductive pad and laterally separated from each other.

### BACKGROUND

The semiconductor industry continues to improve the integration density of various electronic components (e.g., transistors, diodes, resistors, capacitors, etc.) by continual reductions in minimum feature size, which allow more components to be integrated into a given area. The individual dies are typically packaged separately. A package not only provides protection for semiconductor devices from environmental contaminants, but also provides a connection interface for the semiconductor devices packaged therein.

Three dimensional integrated circuits (3DICs) are a recent development in semiconductor packaging in which multiple semiconductor dies are stacked upon one another, such as package-on-package (POP) and system-in-package (SiP) packaging techniques. Some 3DICs are prepared by placing dies over dies on a semiconductor wafer level. 3DICs provide improved integration density and other advantages, such as faster speeds and higher bandwidth, because of the decreased length of interconnects between the stacked dies, as examples. However, there are many challenges related to 3DICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a top view of a semiconductor package, in accordance with some embodiments.

FIG. 2 is a cross-sectional view of the semiconductor package of FIG. 1 along the sectional line A-A, in accordance with some embodiments.

FIG. 3A to FIG. 3I are enlarged cross-sectional views illustrating various stages of forming part of the semiconductor package, in accordance with some embodiments.

FIG. 4A to FIG. 4F are enlarged cross-sectional views illustrating various stages of forming part of the semiconductor package, in accordance with some embodiments.

FIG. 5 is a perspective view of a pillar bump structure, in accordance with some embodiments.

FIG. 6A to FIG. 6D are top views illustrating different configurations of a pillar bump structure with at least two protrusions and one or more sets of a plurality of lower stacked vias, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a lower feature over or on a upper feature in the description that follows may include embodiments in which the lower and upper features are formed in direct contact, and may also include embodiments in which additional features may be formed between the lower and upper features, such that the lower and upper features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

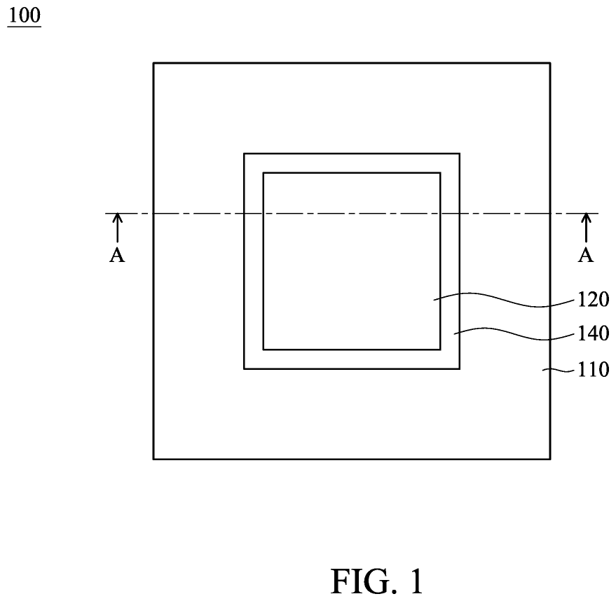

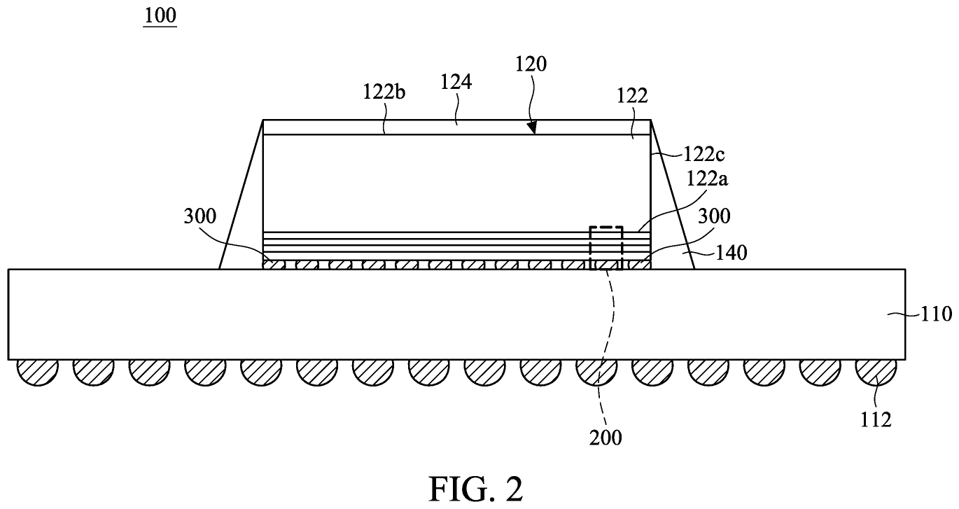

FIG. 1 is a top view of a semiconductor package 100, in accordance with some embodiments. FIG. 2 is a cross-sectional view of the semiconductor package 100 of FIG. 1 along the sectional line A-A, in accordance with some embodiments. A substrate 110 is provided, in accordance with some embodiments. The substrate 110 may be a printed circuit board (PCB), a chip, or another suitable structure with metal lines and pads. In some embodiments, the substrate 110 includes a plurality of dielectric layers, a plurality of metal lines, a plurality of metal vias, and a plurality of metal bonding pads. The metal lines, the metal vias, and the metal bonding pads are formed in the dielectric layers, in accordance with some embodiments. The metal lines, the metal vias, and the metal bonding pads are electrically connected to each other. The dielectric layers may be made of an insulating material, such as oxides, e.g., silicon oxide (SiO₂), in accordance with some embodiments. The metal lines, the metal vias, and the metal bonding pads are made of metal (e.g., copper, aluminum, gold, silver, or tungsten) or alloy thereof, in accordance with some embodiments.

A plurality of conductive connectors 112 may be formed under the substrate 110. In some embodiments, the conductive connectors 112 are C4 bumps, solder bumps, copper bumps, micro bumps, ENEPIG formed bumps, BGA bumps, copper pillars, and the like. The conductive connectors 112 may be electrically connected to the metal bonding pads formed in the dielectric layers in the substrate 110, in accordance with some embodiments.

A semiconductor die 120 is provided, as shown in FIG. 2 in accordance with some embodiments. The semiconductor die 120 includes a substrate 122, an interfacial layer 124, and an interconnect structure, in accordance with some embodiments. The substrate 122 has a front surface 122a, a back surface 122b, and sidewalls 122c, in accordance with some embodiments.

The substrate 122 includes, for example, a semiconductor substrate. In some embodiments, the substrate 122 is made of an elementary semiconductor material including silicon or germanium in a single crystal, polycrystal, or amorphous structure. In some embodiments, the substrate 122 is made of a compound semiconductor, such as silicon carbide, gallium arsenide, gallium phosphide, indium phosphide, indium arsenide, an alloy semiconductor, such as SiGe, or GaAsP, or a combination thereof. The substrate 122 may also include multi-layer semiconductors, semiconductor on insulator (SOI) (such as silicon on insulator or germanium on insulator), or a combination thereof.

In some embodiments, the substrate 122 includes various device elements. In some embodiments, the various device elements are formed in substrate 122 and/or over the substrate 122. The device elements are not shown in figures for the purpose of simplicity and clarity. Examples of the various devices include active devices, passive devices, other suitable devices, or a combination thereof. The active devices may include transistors or diodes (not shown) formed at the front surface 122a. The passive devices include resistors, capacitors, or other suitable passive devices. For example, the transistors include metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 122. The isolation features are used to define active regions and electrically isolate various device elements formed in and/or over the substrate 122 in the active regions. In some embodiments, the isolation features include shallow trench isolation (STI) features, local oxidation of silicon (LOCOS) features, other suitable isolation features, or a combination thereof.

The interconnect structure, including an upper interconnect structure and a lower interconnect structure, is formed at the front surface 122a, in accordance with some embodiments. Details of the interconnect structure will be discussed below.

The interfacial layer 124 is formed at the back surface 122b of the substrate 122, in accordance with some embodiments. The interfacial layer 124 includes a titanium layer (not shown), a nickel-vanadium (NiV) layer (not shown), and a gold layer (not shown) sequentially stacked over the back surface 122b, in accordance with some embodiments.

The semiconductor die 120 is bonded to the substrate 110 through a plurality of pillar bump structures 300, in accordance with some embodiments. The pillar bump structures 300 are made of a conductive material, such as a solder material (e.g., tin), in accordance with some embodiments. The pillar bump structures 300 are bonded to the metal bonding pads formed in the dielectric layers in the substrate 110, in accordance with some embodiments.

An underfill layer 140 is formed over the substrate 110, in accordance with some embodiments. The underfill layer 140 may be in contact with the sidewalls 122c of the semiconductor die 120, in accordance with some embodiments. The underfill layer 140 surrounds the pillar bump structures 300, in accordance with some embodiments. The underfill layer 140 surrounds the semiconductor die 120, in accordance with some embodiments. The underfill layer 140 includes an insulating material (e.g., a polymer material), in accordance with some embodiments. The underfill layer 140 has a ring shape in a top view, in accordance with some embodiments.

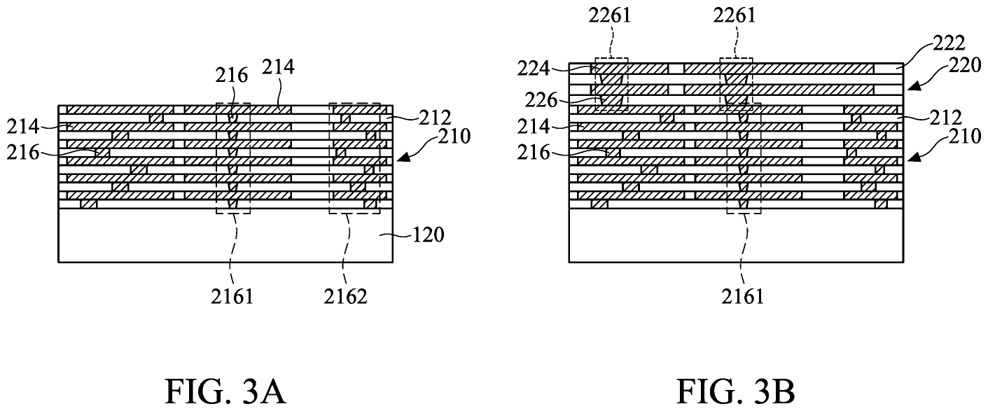

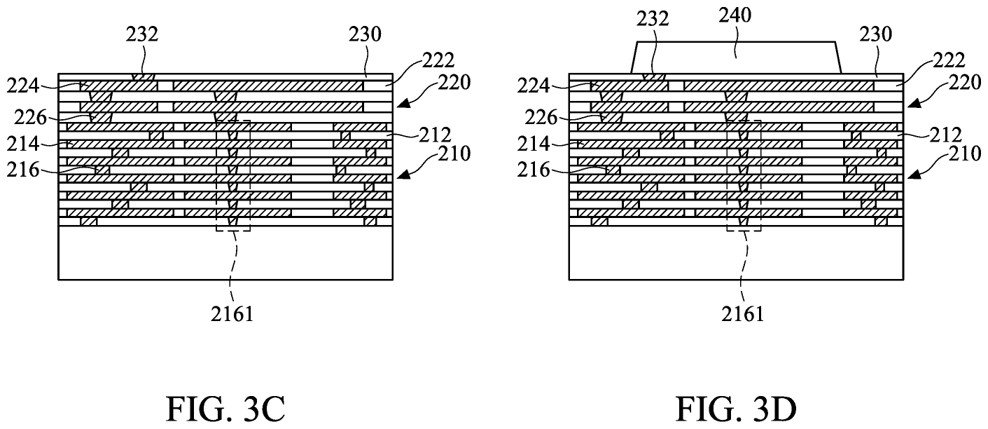

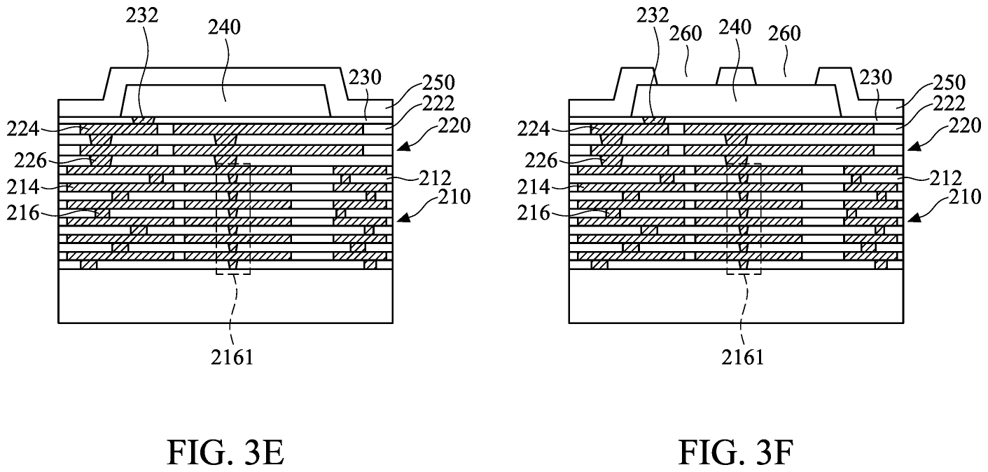

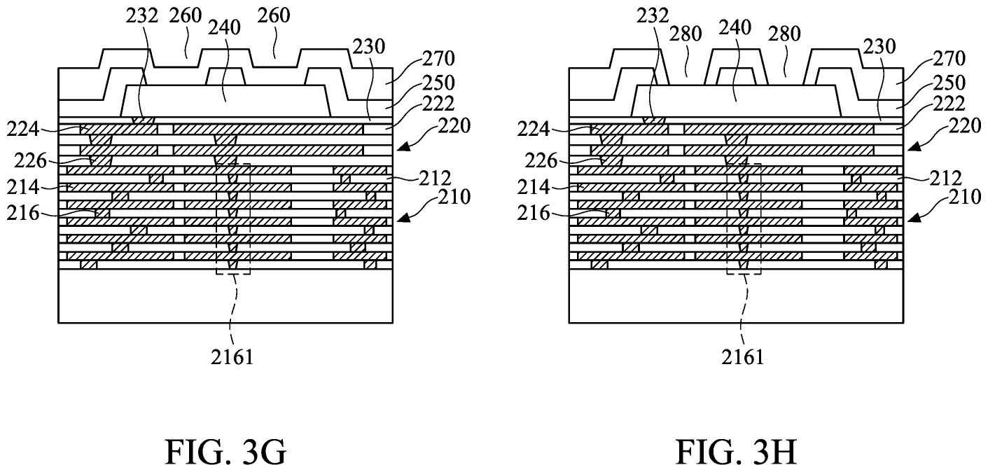

Next, FIG. 3A to FIG. 3I. FIG. 3A to FIG. 3I are enlarged cross-sectional views illustrating various stages of forming part of the semiconductor package 100 (e.g., in region 200 shown in FIG. 2), in accordance with some embodiments. It should be noted that the perspectives of FIG. 3A to FIG. 3I are upside-down. The spatially relative terms, such as “upper” and “lower”, used herein may be changed during the manufacturing processes and are not intended to be limiting.

A lower interconnect structure 210 is formed over the semiconductor die 120, as shown in FIG. 3A in accordance with some embodiments. For example, the lower interconnect structure 210 is formed over the front surface 122a of the substrate 122. The lower interconnect structure 210 includes a plurality of lower dielectric layers 212. The lower interconnect structure 210 also includes a plurality of lower metal lines 214 and a plurality of lower metal vias 216 formed in the lower dielectric layers 212.

In some embodiments, the lower dielectric layers 212 may include low-k dielectric materials or extremely low-k (ELK) dielectric materials. For example, the dielectric constants (k values) of low-k dielectric materials may be lower than about 3.0. For example, the dielectric constants (k values) of ELK dielectric materials may be less than about 2.5. The lower dielectric layers 212 may include carbon-containing low-k dielectric materials, Hydrogen silsesquioxane (HSQ), Methylsilsesquioxane (MSQ), porous carbon doped silicon dioxide, and the like.

The lower dielectric layers 212 may be formed over the semiconductor die 120 by chemical vapor deposition (CVD), physical vapor deposition (PVD), plasma enhanced chemical vapor deposition (PECVD), spin coating, lamination or another suitable deposition technique. In some embodiments, the formation of the lower dielectric layers 212 includes depositing a porogen-containing dielectric material in the lower dielectric layers 212 and then performing a curing process to drive out the porogen, and hence the remaining lower dielectric layers 212 are porous. With successive layers of dielectric and copper (or another suitable metal fill material), a multilayer metal interconnect structure (i.e., the lower interconnect structure 210) is formed.

The lower metal lines 214 and the lower metal vias 216 may be formed in different lower dielectric layers 212. The lower metal lines 214 and the lower metal vias 216 may include copper or copper alloys, and they may also include other metals. The formation of the lower metal lines 214 and the lower metal vias 216 in the lower dielectric layers 212 may include single damascene processes and/or dual damascene processes. Single damascene processes generally form and fill a single feature with copper or another suitable metal fill material per damascene stage. Dual damascene processes generally form and fill two features with copper or another suitable metal fill material at once, e.g., a trench overlying a via may both be filled with a single copper or another suitable metal fill material deposition using dual damascene processes.

In a single damascene process for forming a metal line or a via, a trench or a via opening is first formed in one of the lower dielectric layers 212, followed by filling the trench or the via opening with a conductive material. A planarization process such as a chemical mechanical planarization (CMP) process is then performed to remove the excess portions of the conductive material higher than the top surface of the dielectric layer, leaving a metal line or a via in the corresponding trench or via opening. In a dual damascene process, both of a trench and a via opening may be formed in a dielectric layer, with the via opening underlying and connected to the trench. Conductive materials are then filled into the trench and the via opening to form a metal line and a via, respectively. The conductive materials may include a diffusion barrier layer and a copper-containing metallic material over the diffusion barrier layer. The diffusion barrier layer may include titanium, titanium nitride, tantalum, tantalum nitride, and the like.

The lower metal vias 216 may include a plurality of lower stacked vias 2161 located in different lower dielectric layers 212 and electrically connected to each other. In addition, the lower metal vias 216 may also include a plurality of lower non-stacked vias 2162 located in different lower dielectric layers 212 and electrically connected to each other. The horizontal distance between any two of the lower stacked vias 2161 is less than about 38 nm, while the horizontal distance between two of the lower non-stacked vias 2162 is greater than about 38 nm.

An upper interconnect structure 220 is formed over the lower interconnect structure 210, as shown in FIG. 3B in accordance with some embodiments. The upper interconnect structure 220 includes a plurality of upper dielectric layers 222. The upper interconnect structure 220 also includes a plurality of upper metal lines 224 and a plurality of upper metal vias 226 formed in the upper dielectric layers 222. The upper dielectric layers 222 may include a dielectric polymer material such as polyimide (PI), benzocyclobutene (BCB), or polybenzobisoxazole (PBO). Other suitable materials are within the contemplated scope of disclosure. In some embodiments, the upper dielectric layers 222 may include undoped silica glass (USG). In some embodiments, the materials of the upper dielectric layers 222 are different from the materials of the lower dielectric layers 212.

The upper dielectric layers 222 may be formed over the lower interconnect structure 210 by chemical vapor deposition (CVD), physical vapor deposition (PVD), plasma enhanced chemical vapor deposition (PECVD), spin coating, lamination or another suitable deposition technique. With successive layers of dielectric and copper (or another suitable metal fill material), a multilayer metal interconnect structure (i.e., the upper interconnect structure 220) is formed.

The upper metal lines 224 and the upper metal vias 226 may be formed in different upper dielectric layers 222. The upper metal lines 224 and the upper metal vias 226 may include copper or copper alloys, and they may also include other metals. The formation of the upper metal lines 224 and the upper metal vias 226 in the upper dielectric layers 222 may include single damascene processes and/or dual damascene processes. Single damascene processes generally form and fill a single feature with copper or another suitable metal fill material per damascene stage. Dual damascene processes generally form and fill two features with copper or another suitable metal fill material at once, e.g., a trench overlying a via may both be filled with a single copper or another suitable metal fill material deposition using dual damascene processes.

In a single damascene process for forming a metal line or a via, a trench or a via opening is first formed in one of the upper dielectric layers 222, followed by filling the trench or the via opening with a conductive material. A planarization process such as a chemical mechanical planarization (CMP) process is then performed to remove the excess portions of the conductive material higher than the top surface of the dielectric layer, leaving a metal line or a via in the corresponding trench or via opening. In a dual damascene process, both of a trench and a via opening may be formed in a dielectric layer, with the via opening underlying and connected to the trench. Conductive materials are then filled into the trench and the via opening to form a metal line and a via, respectively. The conductive materials may include a diffusion barrier layer and a copper-containing metallic material over the diffusion barrier layer. The diffusion barrier layer may include titanium, titanium nitride, tantalum, tantalum nitride, and the like.

The upper metal vias 226 may include a plurality of upper stacked vias 2261 located in different upper dielectric layers 222 and electrically connected to each other. In addition, the upper metal vias 226 may also include a plurality of upper non-stacked vias (not shown) located in different upper dielectric layers 222 and electrically connected to each other. The horizontal distance between any two of the upper stacked vias 2261 is less than about 38 nm, while the horizontal distance between two of the non-upper stacked vias is greater than about 38 nm. In some embodiments, the minimum width of any of the upper stacked vias 2261 is greater than the minimum width of any of the lower stacked vias 2161. Therefore, stress accumulation issues in the lower stacked vias 2161 may be worse than stress accumulation issues in the upper stacked vias 2261.

A first passivation layer 230 including a passivation via 232 formed therein is formed over the upper interconnect structure 220, as shown in FIG. 3C in accordance with some embodiments. The first passivation layer 230 may include silicon oxide or a silicon oxide containing material. The first passivation layer 230 may be deposited by chemical vapor deposition (CVD), physical vapor deposition (PVD), spin coating, lamination or another suitable deposition technique. The passivation via 232 may include copper or copper alloys, and the passivation via 232 may also include other metals.

A conductive pad 240 is formed over the first passivation layer 230, as shown in FIG. 3D in accordance with some embodiments. The conductive pad 240 may include copper or copper alloys, and the conductive pad 240 may also include other metals. The conductive pad 240 may be electrically connected to the lower metal lines 214 and the lower metal vias 216 through the passivation via 232, the upper metal lines 224, and the upper metal vias 226. The conductive pad 240 may be referred to as the redistribution layer (RDL) structure. The RDL structure may be used for three-dimensional integrated circuit (3DIC) integration and for 2.5D IC integration with a passive interposer.

A second passivation layer 250 is formed over the first passivation layer 230 and the conductive pad 240, as shown in FIG. 3E in accordance with some embodiments. The second passivation layer 250 may include silicon oxide or a silicon oxide containing material. The second passivation layer 250 may be deposited by chemical vapor deposition (CVD), physical vapor deposition (PVD), spin coating, lamination or another suitable deposition technique. In some embodiments, the materials of the second passivation layer 250 are different from the materials of the first passivation layer 230. In some embodiments, the thickness of the second passivation layer 250 is greater than the thickness of the first passivation layer 230.

A plurality of gaps 260 are formed in the second passivation layer 250, as shown in FIG. 3F in accordance with some embodiments. The gaps 260 overlap the conductive pad 240 vertically without overlapping the lower stacked vias 2161 vertically. For example, a suitable combination of photolithography processes (such as photoresist deposition, exposure, and development) may be used to pattern an etch mask layer to form a patterned etch mask layer. Then, an etching process may be performed using the etch mask layer as the mask to form the gaps 260 in the second passivation layer 250. After the gaps 260 are formed, the patterned etch mask layer is removed in accordance with some embodiments. In some embodiments, more than two gaps 260 are formed in the second passivation layer 250.

A polymeric layer 270 is formed over the second passivation layer 250 and on sidewalls of the gaps 260, as shown in FIG. 3G in accordance with some embodiments. In some embodiments, the polymeric layer 270 may include polymer materials, such as benzocyclobutene (BCB) polymer, polyimide (PI), or polybenzoxazole (PBO). The polymeric layer 270 may be formed over the second passivation layer 250 and on sidewalls of the gaps 260 by chemical vapor deposition (CVD), physical vapor deposition (PVD), plasma enhanced chemical vapor deposition (PECVD), spin coating, lamination or another suitable deposition technique.

A plurality of openings 280 are formed in the second passivation layer 250 and the polymeric layer 270, as shown in FIG. 3H in accordance with some embodiments. The openings 280 overlap the conductive pad 240 vertically without overlapping the lower stacked vias 2161 vertically. For example, a suitable combination of photolithography processes (such as photoresist deposition, exposure, and development) may be used to pattern an etch mask layer to form a patterned etch mask layer. Then, an etching process may be performed using the etch mask layer as the mask to form the openings 280 in the second passivation layer 250 and the polymeric layer 270. After the openings 280 are formed, the patterned etch mask layer is removed in accordance with some embodiments. In some embodiments, more than two openings 280 are formed in the second passivation layer 250 and the polymeric layer 270.

A pillar bump structure 300 is formed in the openings 280, as shown in FIG. 3I in accordance with some embodiments. In some embodiments, the pillar bump structure 300 may be made of a conductive material, such as copper, tungsten, gold, silver, aluminum, lead, tin, tantalum, and the like. In addition, the pillar bump structure 300 may contain an adhesion layer and/or a wetting layer. In some embodiments, the pillar bump structure 300 further includes a copper seed layer. In some embodiments, the pillar bump structure 300 includes an adhesion layer made of Ti/Cu and a wetting layer made of Cu. In some embodiments, the pillar bump structure 300 is formed by a plating process, such as an electrochemical plating process or an electroless process. After the the pillar bump structure 300 is formed, the pillar bump structure 300 includes at least two protrusions (e.g., a first protrusion 310 and a second protrusion 320) protruding toward the conductive pad 240.

The semiconductor package 100 may include the lower interconnect structure 210, the upper interconnect structure 220, the conductive pad 240, and the pillar bump structure 300. The lower interconnect structure 210 includes the lower dielectric layers 212. The lower interconnect structure 210 also includes the lower metal lines 214 and the lower metal vias 216 formed in the lower dielectric layers 212. The lower metal vias 216 include lower stacked vias 2161 located in different lower dielectric layers 212. The lower stacked vias 2161 are electrically connected to each other, and the horizontal distance between any two of lower stacked vias 2161 is less than about 38 nm. The upper interconnect structure 220 is formed over the lower interconnect structure 210. The upper interconnect structure 220 includes the upper dielectric layers 222. The upper interconnect structure 220 also includes the upper metal lines 224 and the upper metal vias 226 formed in the upper dielectric layers 222. The material of the upper dielectric layers 222 may be different from the material of the lower dielectric layers 212.

The conductive pad 240 is formed over the upper interconnect structure 220. The pillar bump structure 300 is in direct contact with the conductive pad 240. The pillar bump structure 300 may include at least two protrusions (e.g., the first protrusion 310 and the second protrusion 320) protruding toward the conductive pad 240. The protrusions overlap the conductive pad 240 vertically without overlapping the lower stacked vias 2161 vertically. Therefore, the stress accumulated in the lower stacked vias 2161 may be reduced. It should be noted that, although not shown, the protrusions of the pillar bump structure 300 may overlap upper stacked vias 2261 vertically without causing stress accumulation in the upper stacked vias 2261 because the minimum width of any of the upper stacked vias 2261 is greater than the minimum width of any of the lower stacked vias 2161.

The semiconductor package 100 may further include the first passivation layer 230 formed over the upper interconnect structure 220. The first passivation layer 230 may include the passivation via 232 for providing electrical connection. For example, the conductive pad 240 is electrically connected to upper metal lines 224 and upper metal vias 226 through the passivation via 232. The semiconductor package 100 may further include the second passivation layer 250 formed between the pillar bump structure 300 and the first passivation layer 230. The semiconductor package 100 may further include the polymeric layer 270 located between the pillar bump structure 300 and the second passivation layer 250. In some embodiments, the first protrusion 310 and the second protrusion 320 both extend into the polymeric layer 270.

In some embodiments, a portion 252 of the second passivation layer 250 is laterally sandwiched by the first protrusion 310 and the second protrusion 320. In some embodiments, a portion 272 of the polymeric layer 270 is laterally sandwiched by the first protrusion 310 and the second protrusion 320. In addition, the portion 252 and the portion 272 may overlap the lower stacked vias 2161 vertically. In some embodiments, the projection area of the first protrusion 310 of the pillar bump structure 300 is spaced apart from the projection areas of the lower stacked vias 2161. In some embodiments, the projection area of the second protrusion 320 of the pillar bump structure 300 is spaced apart from the projection areas of the lower stacked vias 2161.

In some embodiments, the semiconductor die 120 may be electrically connected to the pillar bump structure 300 through the lower metal lines 214, the lower metal vias 216, the upper metal lines 224, the upper metal vias 226, the passivation via 232, and the conductive pad 240.

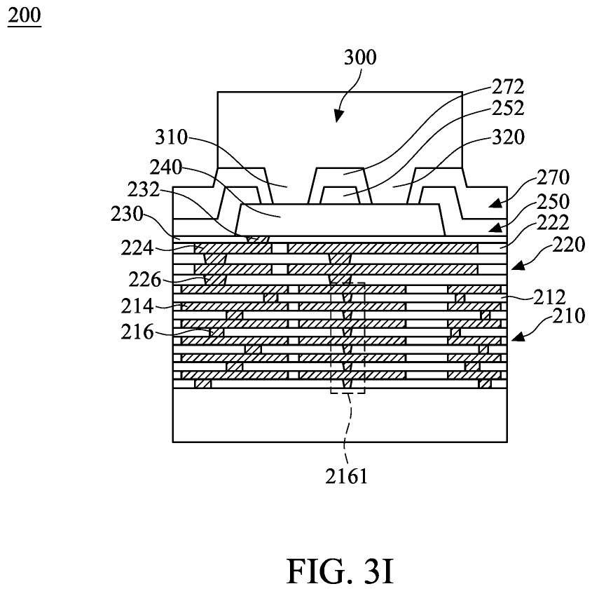

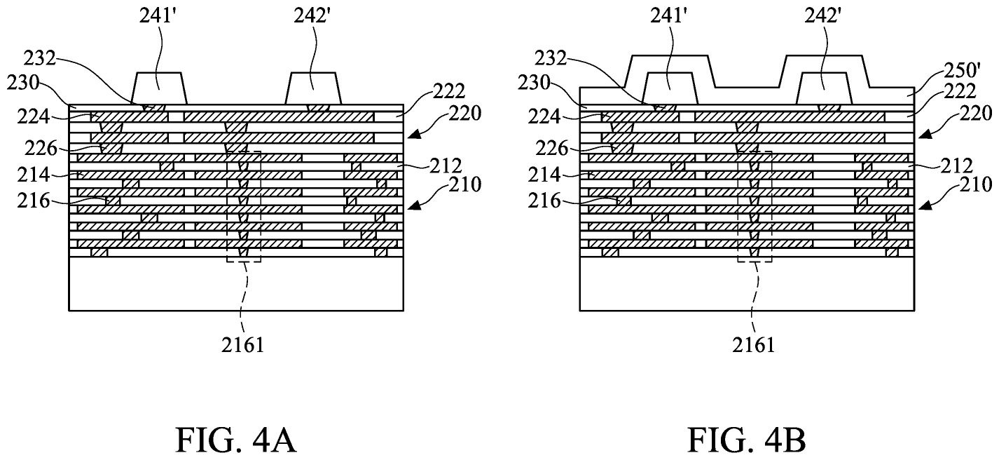

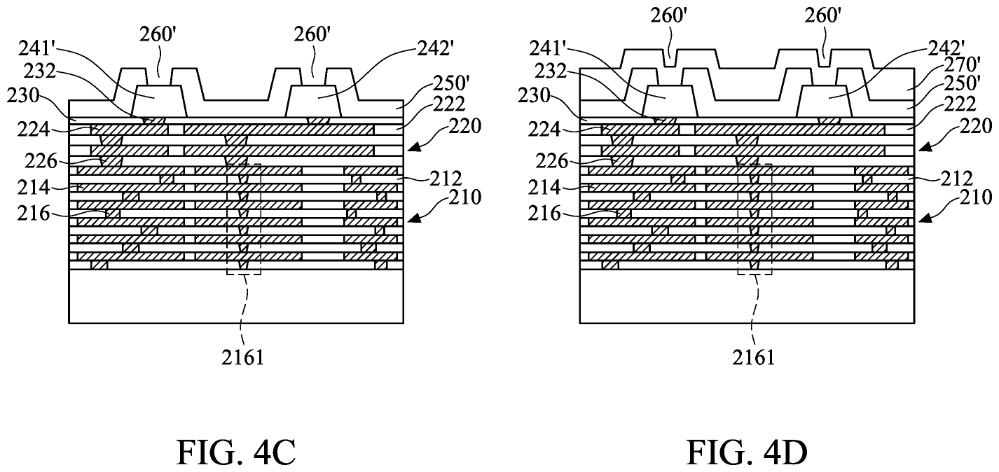

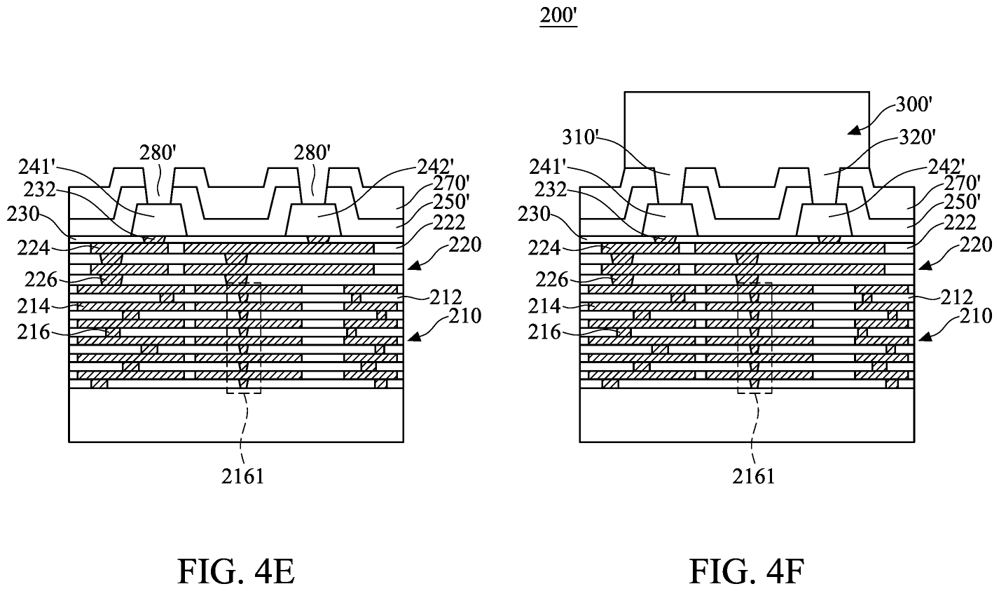

Similar or identical elements will be denoted by similar or identical symbols in the following description. Next, please refer to FIG. 4A to FIG. 4F. FIG. 4A to FIG. 4F are enlarged cross-sectional views illustrating various stages of forming part of the semiconductor package 100 (e.g., a region 200′), in accordance with some embodiments. One of the main differences between the embodiments illustrated in FIG. 3A to FIG. 3I and the embodiments illustrated in FIG. 4A to FIG. 4F is the number of the conductive pads. The description related to the lower interconnect structure 210, the upper interconnect structure 220, the first passivation layer 230 is not repeated.

More than one conductive pad (e.g., a first conductive pad 241′ and a second conductive pad 242′) are formed over the first passivation layer 230, as shown in FIG. 4A in accordance with some embodiments. The first conductive pad 241′ and the second conductive pad 242′ may include copper or copper alloys, and first conductive pad 241′ and the second conductive pad 242′ may also include other metals. The first conductive pad 241′ and the second conductive pad 242′ may be electrically connected to the lower metal lines 214 and the lower metal vias 216 through the passivation via 232, the upper metal lines 224, and the upper metal vias 226. The first conductive pad 241′ and the second conductive pad 242′ may both be referred to as the redistribution layer (RDL) structure.

A second passivation layer 250′ is formed over the first passivation layer 230 and the first conductive pad 241′ and the second conductive pad 242′, as shown in FIG. 4B in accordance with some embodiments. The second passivation layer 250′ may include silicon oxide or a silicon oxide containing material. The second passivation layer 250′ may be deposited by chemical vapor deposition (CVD), physical vapor deposition (PVD), spin coating, lamination or another suitable deposition technique. In some embodiments, the materials of the second passivation layer 250′ are different from the materials of the first passivation layer 230. In some embodiments, the thickness of the second passivation layer 250′ is greater than the thickness of the first passivation layer 230.

A plurality of gaps 260′ are formed in the second passivation layer 250, as shown in FIG. 4C in accordance with some embodiments. The gaps 260′ overlap the first conductive pad 241′ and the second conductive pad 242′ vertically without overlapping the lower stacked vias 2161 vertically. For example, a suitable combination of photolithography processes (such as photoresist deposition, exposure, and development) may be used to pattern an etch mask layer to form a patterned etch mask layer. Then, an etching process may be performed using the etch mask layer as the mask to form the gaps 260′ in the second passivation layer 250′. After the gaps 260′ are formed, the patterned etch mask layer is removed in accordance with some embodiments. In some embodiments, more than two gaps 260′ are formed in the second passivation layer 250′.

A polymeric layer 270′ is formed over the second passivation layer 250′ and on sidewalls of the gaps 260′, as shown in FIG. 4D in accordance with some embodiments. In some embodiments, the polymeric layer 270′ may include polymer materials, such as benzocyclobutene (BCB) polymer, polyimide (PI), or polybenzoxazole (PBO). The polymeric layer 270′ may be formed over the second passivation layer 250′ and on sidewalls of the gaps 260′ by chemical vapor deposition (CVD), physical vapor deposition (PVD), plasma enhanced chemical vapor deposition (PECVD), spin coating, lamination or another suitable deposition technique.

A plurality of openings 280′ are formed in the second passivation layer 250′ and the polymeric layer 270′, as shown in FIG. 4E in accordance with some embodiments. The openings 280′ overlap the first conductive pad 241′ and the second conductive pad 242′ vertically without overlapping the lower stacked vias 2161 vertically. For example, a suitable combination of photolithography processes (such as photoresist deposition, exposure, and development) may be used to pattern an etch mask layer to form a patterned etch mask layer. Then, an etching process may be performed using the etch mask layer as the mask to form the openings 280′ in the second passivation layer 250′ and the polymeric layer 270′. After the openings 280′ are formed, the patterned etch mask layer is removed in accordance with some embodiments. In some embodiments, more than two openings 280′ are formed in the second passivation layer 250′ and the polymeric layer 270.

A pillar bump structure 300′ is formed in the openings 280′, as shown in FIG. 4F in accordance with some embodiments. In some embodiments, the pillar bump structure 300′ may be made of a conductive material, such as copper, tungsten, gold, silver, aluminum, lead, tin, tantalum, and the like. In addition, the pillar bump structure 300 may contain an adhesion layer and/or a wetting layer. In some embodiments, the pillar bump structure 300′ further includes a copper seed layer. In some embodiments, the pillar bump structure 300′ includes an adhesion layer made of Ti/Cu and a wetting layer made of Cu. In some embodiments, the pillar bump structure 300′ is formed by a plating process, such as an electrochemical plating process or an electroless process. After the the pillar bump structure 300′ is formed, the pillar bump structure 300′ includes at least two protrusions (e.g., a first protrusion 310′ and a second protrusion 320′) protruding toward the first conductive pad 241′ and the second conductive pad 242′, respectively.

The semiconductor package 100 may include the lower interconnect structure 210, the upper interconnect structure 220, the first conductive pad 241′, the second conductive pad 242′, and the pillar bump structure 300′. The pillar bump structure 300′ is in direct contact with the first conductive pad 241′ and the second conductive pad 242′. The pillar bump structure 300′ may include the first protrusion 310′ and the second protrusion 320′ protruding toward the first conductive pad 241′ and the second conductive pad 242′, respectively. In some embodiments, the first protrusion 310′ is in direct contact with the top surface of the first conductive pad 241′, and the second protrusion 320′ is in direct contact with the top surface of the second conductive pad 242′. The first protrusion 310′ overlaps the first conductive pad 241′ without overlapping the lower stacked vias 2161 vertically, and the second protrusion 320′ overlaps the second conductive pad 242′ vertically without overlapping the lower stacked vias 2161 vertically. Therefore, the stress accumulated in the lower stacked vias 2161 may be reduced.

In some embodiments, the semiconductor die 120 may be electrically connected to the pillar bump structure 300′ through the lower metal lines 214, the lower metal vias 216, the upper metal lines 224, the upper metal vias 226, the passivation via 232, the first conductive pad 241′, and the second conductive pad 242′.

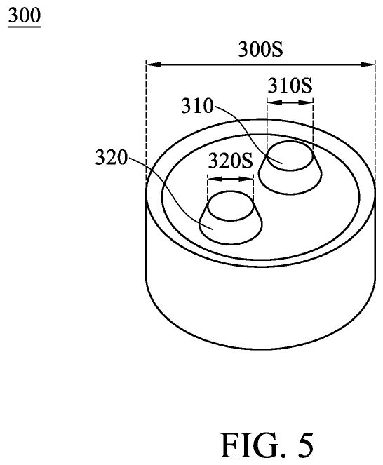

Please refer to FIG. 5. FIG. 5 is a perspective view of the pillar bump structure 300 (or 300′, they have similar structures), in accordance with some embodiments. The pillar bump structure 300 includes the first protrusion 310 and the second protrusion 320. In a bottom view, the pillar bump structure 300 has a diameter 300S, and the area of the pillar bump structure 300 is (300S/2)²π. In a bottom view, the first protrusion 310 has a first diameter 310S, the second protrusion 320 has a second diameter 320S, the area of the first protrusion 310 is (310S/2)²π, and the area of the second protrusion 320 is (320S/2)²π. In some embodiments, in a bottom view, the ratio of the combined area of the first protrusion 310 and the second protrusion 320 to the area of the pillar bump structure 300 is in a range between 0.10 and 0.75. In other words, the ratio satisfies the following equation:

$$0.1 \leq \frac{{( \frac{300 S}{2} )}^{2} π}{{( \frac{310 S}{2} )}^{2} π + {( \frac{320 S}{2} )}^{2} π} \leq 0.75 .$$

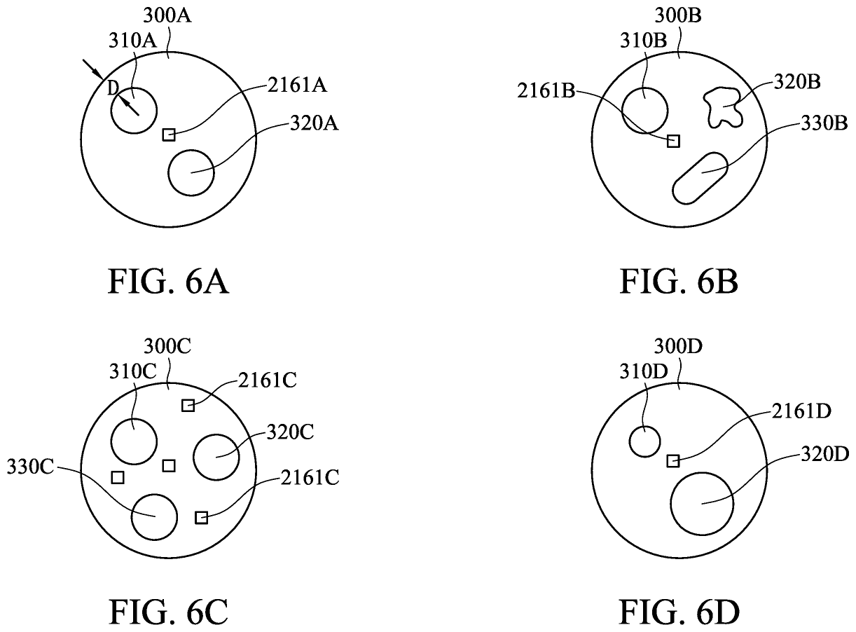

It should be noted that the number, the shape, and the configurations of the protrusions may vary according to actual needs. In some embodiments, the pillar bump structure 300 may include more than three protrusions, such as four or more, and the ratio of the combined area of all the protrusions to the area of the pillar bump structure may still be in a range between 0.10 and 0.75. Please refer to FIG. 6A to FIG. 6D. FIG. 6A to FIG. 6D are top views illustrating different configurations of a pillar bump structure with at least two protrusions and one or more sets of a plurality of lower stacked vias, in accordance with some embodiments. For ease of illustration, the pillar bump structure, the protrusions, and the lower stacked vias are simplified, but they may be similar to the pillar bump structure 300, the first protrusion 310 (or the second protrusion 320), and the lower stacked vias 2161. All the protrusions do not overlap the lower stacked vias vertically, as shown in FIG. 6A to FIG. 6D in accordance with some embodiments. Therefore, the stress accumulated in the lower stacked vias may be reduced.

A pillar bump structure 300A having a first protrusion 310A and a second protrusion 320A are illustrated in FIG. 6A in accordance with some embodiments. In addition, there is one set of lower stacked vias 2161A. In some embodiments, the lower stacked vias 2161A is located between the first protrusion 310A and the second protrusion 320A. In a bottom view, the first area of the first protrusion 310A is substantially the same as the second area of the second protrusion 320A. In a bottom view, the first shape of the first protrusion 310A is substantially the same as the second shape of the second protrusion 320A. In some embodiments, in a bottom view, the distance D between the edge of the pillar bump structure 300A and the edge of the first protrusion 310A is greater than 6000 nm. Therefore, the formation of the first protrusion 310A can be accomplished more easily without being affected by the surrounding layers.

A pillar bump structure 300B having a first protrusion 310B, a second protrusion 320B, and a third protrusion 330B are illustrated in FIG. 6B in accordance with some embodiments. In addition, there are one set of lower stacked vias 2161B. In a bottom view, the first area of the first protrusion 310B, the second area of the second protrusion 320B, the third area of the third protrusion 330B may be different. In a bottom view, the first area of the first protrusion 310B, the second area of the second protrusion 320B, the third area of the third protrusion 330B may be different.

A pillar bump structure 300C having a first protrusion 310C, a second protrusion 320C, and a third protrusion 330C are illustrated in FIG. 6C in accordance with some embodiments. In addition, there are more than one set of lower stacked vias 2161C. In a bottom view, the first area of the first protrusion 310C, the second area of the second protrusion 320C, the third area of the third protrusion 330C are substantially the same.

A pillar bump structure 300D having a first protrusion 310D and a second protrusion 320D are illustrated in FIG. 6D in accordance with some embodiments. In addition, there is one set of lower stacked vias 2161D. In some embodiments, the lower stacked vias 2161D is located between the first protrusion 310D and the second protrusion 320D. In a bottom view, the first area of the first protrusion 310D is different from the second area of the second protrusion 320D. In a bottom view, the first shape of the first protrusion 310D is substantially the same as the second shape of the second protrusion 320D.

As described above, a semiconductor package is provided. The semiconductor package includes an interconnect structure including a plurality of stacked vias formed therein and a pillar bump structure with at least two protrusions. The protrusions do not overlap the stacked vias vertically, and thus stress accumulation in the stacked vias is reduced, yield is increased, and manufacturing processes are optimized.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

A semiconductor package is provided in accordance with some embodiments. The semiconductor package includes a semiconductor substrate, a lower interconnect structure, an upper interconnect structure, a conductive pad, and a pillar bump. The lower interconnect structure is formed over the semiconductor substrate. The lower interconnect structure includes a plurality of lower dielectric layers. The lower interconnect structure also includes a plurality of lower metal lines and a plurality of lower metal vias formed in the lower dielectric layers. The upper interconnect structure is formed over the lower interconnect structure. The conductive pad is formed over the upper interconnect structure. The pillar bump structure is in direct contact with the conductive pad. The pillar bump structure includes at least two protrusions protruding toward the conductive pad and laterally separated from each other.

In some embodiments, in a bottom view, the ratio of area of the at least two protrusions to the area of the pillar bump structure is in a range between 0.10 and 0.75. In some embodiments, the lower metal vias include a plurality of lower stacked vias located in different lower dielectric layers and electrically connected to each other, and the horizontal distance between any two of lower stacked vias is less than about 38 nm. In some embodiments, the at least two protrusions overlap the conductive pad vertically without overlapping lower stacked vias vertically.

In some embodiments, the upper metal vias include a plurality of upper stacked vias located in different upper dielectric layers and electrically connected to each other. In some embodiments, the minimum width of any of the upper stacked vias is greater than the minimum width of any of the lower stacked vias. In some embodiments, the at least two protrusions overlap upper stacked vias vertically. In some embodiments, the lower metal vias include a plurality of lower non-stacked vias located in different lower dielectric layers and electrically connected to each other, and the horizontal distance between two of lower non-stacked vias is greater than about 38 nm.

In some embodiments, the semiconductor package further includes a first passivation layer formed over the upper interconnect structure. The first passivation layer includes a passivation via, and the conductive pad is electrically connected to upper metal lines and upper metal vias through the passivation via. In some embodiments, the semiconductor package further includes a second passivation layer formed between the pillar bump structure and the first passivation layer. In some embodiments, the semiconductor package further includes a polymeric layer located between the pillar bump structure and the second passivation layer. In some embodiments, the semiconductor package further includes a portion of the second passivation layer and a portion of the polymeric layer are located between the at least two protrusions.

A semiconductor package is provided in accordance with some embodiments. The semiconductor package includes a lower interconnect structure, an upper interconnect structure, and a pillar bump structure. The lower interconnect structure includes a plurality of lower dielectric layers. The lower interconnect structure also includes a plurality of lower metal vias formed in the lower dielectric layers. The lower metal vias include a plurality of lower stacked vias located in different lower dielectric layers. The upper interconnect structure is formed over the lower interconnect structure. The upper interconnect structure includes a plurality of upper dielectric layers. The upper interconnect structure also includes a plurality of upper metal vias formed in the upper dielectric layers. The material of upper dielectric layers is different from the material of lower dielectric layers. The first conductive pad is formed over the upper interconnect structure and electrically connected to the upper metal vias. The pillar bump structure includes a first protrusion and a second protrusion laterally spaced apart from the first protrusion. The first protrusion is in direct contact with the top surface of the first conductive pad.

In some embodiments, the semiconductor package further includes a second conductive pad formed over the upper interconnect structure and electrically connected to the upper metal vias. The second protrusion is in direct contact with the top surface the second conductive pad. In some embodiments, in a bottom view, a first area of the first protrusion is different from a second area of the second protrusion. In some embodiments, in a bottom view, a first shape of the first protrusion is different from a second shape of the second protrusion. In some embodiments, in a bottom view, the lower stacked vias are located between the first protrusion and the second protrusion.

A semiconductor package is provided in accordance with some embodiments. The semiconductor package includes an interconnect structure, a first passivation layer, a second passivation layer, a polymeric layer, and a pillar bump structure. The interconnect structure includes a plurality of dielectric layers. The interconnect structure also includes a plurality of metal lines and a plurality of stacked vias formed in the dielectric layers. The first passivation layer is formed over the interconnect structure. The second passivation layer is formed over the first passivation layer. The polymeric layer is formed over the second passivation layer. The pillar bump structure is formed over the polymeric layer. The pillar bump structure includes a first protrusion extending into the polymeric layer, and the projection area of the first protrusion of the pillar bump structure is spaced apart from the projection areas of the stacked vias.

In some embodiments, the pillar bump structure further includes a second protrusion extending into the polymeric layer, and a portion of the polymeric layer is laterally sandwiched by the first protrusion and the second protrusion. In some embodiments, the projection area of the second protrusion of the pillar bump structure is spaced apart from the projection areas of the stacked vias.

A method for forming a semiconductor package is provided in accordance with some embodiments. The method includes forming a lower interconnect structure and forming an upper interconnect structure over the lower interconnect structure. The lower interconnect structure includes a plurality of lower dielectric layers and a plurality of lower metal lines and a plurality of lower metal vias formed therein. The lower metal vias include a plurality of lower stacked vias located in different lower dielectric layers and electrically connected to each other. The upper interconnect structure includes a plurality of upper dielectric layers and a plurality of upper metal lines and a plurality of upper metal vias formed therein. The method also includes forming a first passivation layer over the upper interconnect structure and forming a conductive pad over the first passivation layer. The first passivation layer includes a passivation via formed therein. The method further includes forming a second passivation layer over the first passivation layer and the conductive pad and forming a polymeric layer over the second passivation layer. The method yet includes forming a plurality of openings in the second passivation layer and the polymeric layer and depositing a conductive material into openings to form a pillar bump structure. The openings overlap the conductive pad vertically without overlapping lower stacked vias vertically.

In some embodiments, the method further includes forming a plurality of gaps in the second passivation layer before the formation of the polymeric layer. The gaps overlap the conductive pad vertically without overlapping lower stacked vias vertically. In some embodiments, forming the openings in the second passivation layer includes forming more than two openings.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a semiconductor substrate;
a lower interconnect structure formed over the semiconductor substrate, wherein the lower interconnect structure comprises a plurality of lower dielectric layers and a plurality of lower metal lines and a plurality of lower metal vias formed in the plurality of lower dielectric layers;
an upper interconnect structure formed over the lower interconnect structure;
a conductive pad over the upper interconnect structure; and
a pillar bump structure in direct contact with the conductive pad,
wherein the pillar bump structure comprises at least two protrusions protruding toward the conductive pad and laterally separated from each other.

2. The semiconductor package as claimed in claim 1, wherein in a bottom view, a ratio of areas of the at least two protrusions to an area of the pillar bump structure is in a range between 0.10 and 0.75.

3. The semiconductor package as claimed in claim 1, wherein the plurality of lower metal vias comprise a plurality of lower stacked vias located in different layers of the plurality of lower dielectric layers and electrically connected to each other, and a horizontal distance between any two of the plurality of lower stacked vias is less than about 38 nm.

4. The semiconductor package as claimed in claim 3, wherein the at least two protrusions overlap the conductive pad vertically without overlapping the plurality of lower stacked vias vertically.

5. The semiconductor package as claimed in claim 3, wherein the upper interconnect structure comprises a plurality of upper dielectric layers and a plurality of upper metal vias formed in the plurality of upper dielectric layers, the plurality of upper metal vias comprise a plurality of upper stacked vias located in different layers of the plurality of upper dielectric layers and electrically connected to each other.

6. The semiconductor package as claimed in claim 5, wherein a minimum width of any of the plurality of upper stacked vias is greater than a minimum width of any of the plurality of lower stacked vias.

7. The semiconductor package as claimed in claim 6, wherein the at least two protrusions overlap the plurality of upper stacked vias vertically.

8. The semiconductor package as claimed in claim 1, wherein the plurality of lower metal vias comprise a plurality of lower non-stacked vias located in different layers of the plurality of lower dielectric layers and electrically connected to each other, and a horizontal distance between two of the plurality of lower non-stacked vias is greater than about 38 nm.

9. The semiconductor package as claimed in claim 1, further comprising a first passivation layer formed over the upper interconnect structure, wherein the first passivation layer comprises a passivation via, and the conductive pad is electrically connected to the plurality of lower metal lines and the plurality of lower metal vias through the passivation via.

10. The semiconductor package as claimed in claim 9, further comprising a second passivation layer formed between the pillar bump structure and the first passivation layer.

11. The semiconductor package as claimed in claim 10, further comprising a polymeric layer located between the pillar bump structure and the second passivation layer.

12. The semiconductor package as claimed in claim 11, wherein a portion of the second passivation layer and a portion of the polymeric layer are located between the at least two protrusions.

13. A semiconductor package, comprising:
a lower interconnect structure comprising a plurality of lower dielectric layers and a plurality of lower metal vias formed in the plurality of lower dielectric layers, wherein the plurality of lower metal vias comprise a plurality of lower stacked vias located in different layers of the plurality of lower dielectric layers;
an upper interconnect structure formed over the lower interconnect structure, wherein the upper interconnect structure comprises a plurality of upper dielectric layers and a plurality of upper metal vias formed in the plurality of upper dielectric layers, and a material of the plurality of upper dielectric layers is different from a material of the plurality of lower dielectric layers;
a first conductive pad formed over the upper interconnect structure and electrically connected to the plurality of upper metal vias; and
a pillar bump structure comprising a first protrusion and a second protrusion laterally spaced apart from the first protrusion, wherein the first protrusion is in direct contact with a top surface of the first conductive pad.

14. The semiconductor package as claimed in claim 13, further comprising a second conductive pad formed over the upper interconnect structure and electrically connected to the plurality of upper metal vias, wherein the second protrusion is in direct contact with a top surface of the second conductive pad.

15. The semiconductor package as claimed in claim 13, wherein in a bottom view, a first area of the first protrusion is different from a second area of the second protrusion.

16. The semiconductor package as claimed in claim 13, wherein in a bottom view, a first shape of the first protrusion is different from a second shape of the second protrusion.

17. The semiconductor package as claimed in claim 13, wherein in a bottom view, the plurality of lower stacked vias are located between the first protrusion and the second protrusion.

18. A semiconductor package, comprising:
an interconnect structure comprising a plurality of dielectric layers and a plurality of metal lines and a plurality of stacked vias formed in the plurality of dielectric layers,
a first passivation layer formed over the interconnect structure;
a second passivation layer formed over the first passivation layer;
a polymeric layer formed over the second passivation layer; and
a pillar bump structure formed over the polymeric layer, wherein the pillar bump structure comprises a first protrusion extending into the polymeric layer, and a projection area of the first protrusion of the pillar bump structure is spaced apart from projection areas of the plurality of stacked vias.

19. The semiconductor package as claimed in claim 18, wherein the pillar bump structure further comprises a second protrusion extending into the polymeric layer, and a portion of the polymeric layer is laterally sandwiched by the first protrusion and the second protrusion.

20. The semiconductor package as claimed in claim 19, wherein a projection area of the second protrusion of the pillar bump structure is spaced apart from the projection areas of the plurality of stacked vias.
